(19) United States
(12) Patent Application Publication
(10) Pub. No.: US 2016/0093760 A1
(43) Pub. Date: Mar. 31, 2016

(54) Tapered Optical Waveguide Coupled to Plasmonic Grating Structure

(71) Applicants: LAMDA GUARD TECHNOLOGIES LIMITED, London (GB); THE BOARD OF REGENTS OF THE UNIVERSITY OF TEXAS SYSTEM, Austin, TX (US)

(72) Inventors: Efthymios Kallos, London (GB); George Palikaras, London (GB); Andrea Alu, Austin, TX (US); Christos Argyropoulos, Austin, TX (US)

(21) Appl. No.: 14/892,156

(22) PCT Filed: May 21, 2013
(86) PCT No.: PCT/GB2013/051333

§ 371 Date: Nov. 18, 2015

(51) Int. Cl. H01L 31/054; G02B 6/10; G02B 6/122

(52) U.S. Cl. CPC H01L 31/0547; G02B 6/1226; G02B 6/1228; G02B 6/107

(57) ABSTRACT

There is provided an optical waveguide comprising: a periodic component comprising a plurality of material elements (101) arranged to receive radiation; and a plurality of tapered waveguides (103), wherein each material element is respectively coupled to a tapered waveguide which tapers outwardly from the material element. The device works as a broadband absorber.

### FIELD

The present disclosure relates to an optical waveguide and a photovoltaic device. The present disclosure also relates to a metamaterial, more specifically, an optical metamaterial. Embodiments relate to a plasmonic waveguide and a plasmonic waveguide absorber. Further embodiments of the present disclosure relate to a metamaterial component or layer for increasing the efficiency of a photovoltaic device.

### BACKGROUND

Global photovoltaic (PV) energy generation capacity grew fivefold to 35 gigawatts between 2007 and 2010, with 75% of the capacity available in Europe. Most PV technologies today are based on crystalline silicon (Si) wafers, with organic PVs largely being regarded as a far-in-the-future option. While silicon absorbs solar light effectively in most of the visible range (350-600 nanometers), it behaves poorly between 600-1,100 nm. In order to compensate for this weak absorption, most PV cells have Si wafer thicknesses between 200-300 nm, and are typically referred to as “optically thick” absorbers. In addition, a pyramidal surface texture is typically utilized in order to scatter incoming light over a wide range of angles, thus increasing the effective path length of the light cell.

However, these approaches have had a significant impact on the basic cost of PV cells as more materials and processing is required. Furthermore, for thick solar cells the photocarrier diffusion length is comparably short, and thus charge carriers generated away from the semiconductor junctions are not effectively collected. This has prevented PV technology from replacing conventional fossil fuel technologies for energy generation. Any technological development that could decrease the cost of PV cells by at least a factor of two would be a straightforward revolution in the industry. Such a development could be achieved by increasing the absorption efficiency of a solar cell, so that near-complete light absorption occurs along with photocarrier current collection.

Some techniques that utilize plasmonics have been investigated so far for increased efficiency, which are targeted towards creating thin-film solar cells with thicknesses 1-2 micrometers (μm). For example, by doping the semiconductor material with 20-100 nm diameter metallic nanoparticles, the particles can act as subwavelength scattering elements or near-field couplers for the incident solar radiation, increasing the effective scattering cross section.

Another method involves the coupling of incident solar radiation into surface plasmon polaritons (SPPs), which are electromagnetic waves that travel along the interfaces of metals and dielectrics. This SPP coupling can be achieved for example by corrugating the metallic back surface of the solar cell. In all these cases, one of the main challenges which remains is that the absorption in the semiconductor material needs to be higher than the plasmon losses in the metal. However, these losses become significant for solar wavelengths beyond 800 nm.

It should be emphasized that enhancing the absorption efficiency of weakly lossy materials offers a double advantage, as not only smaller quantities of absorbing materials can be used, but they can also be of inferior quality, thus in both cases reducing the overall cost of the device.

Aspects of the present disclosure relate to using metamaterials and metamaterial-based configurations to address these problems.

Metamaterials are artificially created materials that can achieve electromagnetic properties that do not occur naturally, such as negative index of refraction or electromagnetic cloaking. While the theoretical properties of metamaterials were first described in the 1960s, in the past 15 years there have been significant developments in the design, engineering and fabrication of such materials. A metamaterial typically consists of a multitude of unit cells, i.e. multiple individual elements (sometimes refer to as “meta-atoms”) that each has a size smaller than the wavelength of operation. These unit cells are microscopically built from conventional materials such as metals and dielectrics. However, their exact shape, geometry, size, orientation and arrangement can macroscopically affect light in an unconventional manner, such as creating resonances or unusual values for the macroscopic permittivity and permeability.

Some examples of available metamaterials are negative index metamaterials, chiral metamaterials, plasmonic metamaterials, photonic metamaterials, etc. Due to their sub wavelength nature, metamaterials that operate at microwave frequencies have a typical unit cell size of a few millimetres, while metamaterials operating at the visible part of the spectrum have a typical unit cell size of a few nanometres. Some metamaterials are also inherently resonant, i.e. they can strongly absorb light at certain narrow range of frequencies.

For conventional materials the electromagnetic parameters such as magnetic permeability and electric permittivity arise from the response of the atoms or molecules that make up the material to an electromagnetic wave being passed through. In the case of metamaterials, these electromagnetic properties are not determined at an atomic or molecular level. Instead these properties are determined by the selection and configuration of a collection of smaller objects that make up the metamaterial. Although such a collection of objects and their structure do not “look” at an atomic level like a conventional material, a metamaterial can nonetheless be designed so that an electromagnetic wave will pass through as if it were passing through a conventional material. Furthermore, because the properties of the metamaterial can be determined from the composition and structure of such small (nanoscale) objects, the electromagnetic properties of the metamaterial such as permittivity and permeability can be accurately tuned on a very small scale.

One particular sub-field of metamaterials are plasmonic materials, which support oscillations of electrical charges at the surfaces of metals at optical frequencies. For example, metals such as silver or gold naturally exhibit these oscillations, leading to negative permittivity at this frequency range, which can be harnessed to produce novel devices such as microscopes with nanometer-scale resolution, nanolenses, nanoantennas, and cloaking coatings.

### SUMMARY

Aspects of the present disclosure are defined in the appended independent claims.

The present disclosure details the process to design and build an improved optical waveguide. More specifically, the present disclosure relates to metamaterials which exhibit phenomena of plasmonic Brewster angle funnelling and adiabatic absorption for plasmonic waveguides. In particular, the inventors have combined plasmonic Brewster angle funnelling and adiabatic absorption to more efficiently couple and guide light using sub-wavelength structures. Notably, embodiments of the present disclosure may be formed as layers and may be readily incorporated into conventional devices, such as photovoltaic devices, to enhance performance.

### BRIEF DESCRIPTION OF THE DRAWINGS

Embodiments of the present disclosure will now be described with reference to the accompanying drawings in which:

FIG. 1 shows a section of a two-dimensional structure for coupling and absorbing incident unpolarised radiation;

FIG. 2 is a cross-sections of a one-dimensional unit cell in accordance with embodiments;

FIG. 3 is an improved optical waveguide in accordance with embodiments comprising a one-dimensional unit cell;

FIGS. 4a, 4b, 4c and 4d are two-dimensional unit cell in accordance with embodiments;

FIGS. 5a, 5b and 5c show a two-dimensional array of two-dimensional unit cells in accordance with embodiments; and

FIG. 6 shows the reflection (S11 parameter) of the incident electric field in the 1D structure of FIG. 2, as the angle of the incident field is varied from 0 to 90 degrees;

FIG. 7 is a graph showing a comparison of absorption performance for arrays of 1D and 2D unit cells; and

FIG. 8 shows the simulated electric field amplitude distribution in a slice of the tapered waveguide structure of FIG. 3 interleaved with a photovoltaic component.

In the figures, like reference numerals refer to like parts.

Embodiments of the present disclosure relate to effects achieved with optical radiation. The term “optical” is used herein to refer to visible, near- and mid-infrared wavelengths. That is, electromagnetic radiation in the range 350 nm to 8 micrometres.

### DETAILED DESCRIPTION OF THE DRAWINGS

There is provided an optical waveguide for coupling and guiding optical radiation. The optical waveguide comprises components which have periodicity. The optical waveguide comprises a plurality of unit cells. The unit cells may comprise active components or elements which are one-dimensional or two-dimensional. One-dimensional components couple and guide radiation of one linear polarisation (for example, vertically polarised light). Two-dimensional components couple and guide both linear polarisations (for example, vertical and horizontally polarised light). It may be appreciated that any number of unit cells may be used to form an optical waveguide in accordance with the present disclosure.

In embodiments, the components of the unit cell may have a sub-wavelength dimension and/or the unit cells may have a sub-wavelength periodicity in one or more directions. In embodiments, the plurality of periodic unit cells form a metamaterial. In other embodiments, the plurality of material elements and/or plurality of tapered waveguides are metamaterials.

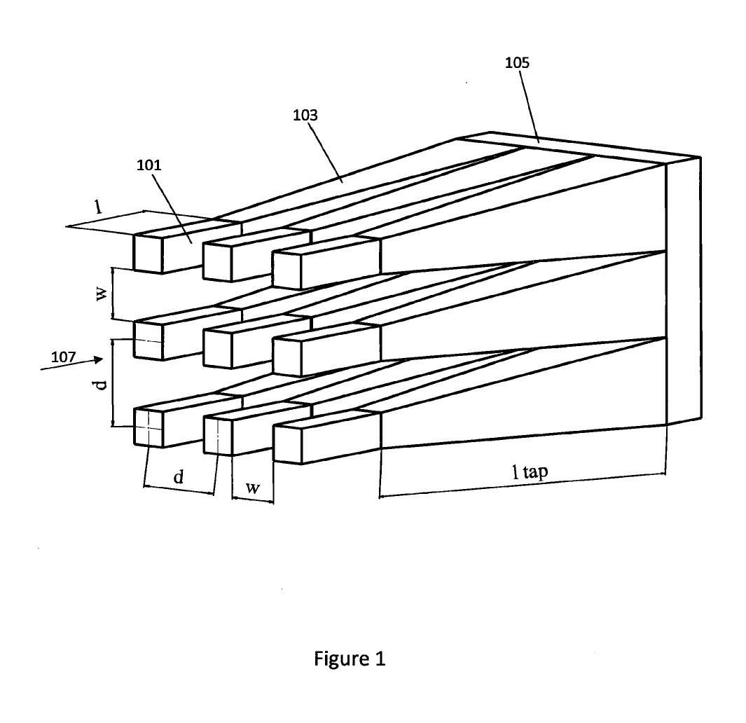

FIG. 1 shows an example optical waveguide in accordance with the present disclosure.

In more detail, FIG. 1 shows a plurality of material elements 101 arranged in a two-dimensional array in a first plane. Each material element 101 is coupled to a tapered waveguide 103 which tapers outwardly from its respective material element to a second plane 105.

In operation, light 107 is coupled by the array of material elements 101 and guided towards the second plane by the tapered waveguides 103. In this respect, it may be understood that the array of material elements “capture” or “absorb” radiation incident on the first plane. Likewise, it may be understood that the tapered elements guide the captured radiation towards the second plane. However, the optical waveguide in accordance with the present disclosure does not accomplish this by conventional means.

In summary, the improved optical waveguide in accordance with the present disclosure relies on strictly non-resonant phenomena of metamaterials to achieve broadband emission and light guiding with controllable angular selectivity, spanning with a single device THz, IR and visible frequencies. The improved device disclosed herein is based on the combination of two non-resonant effects: plasmonic Brewster light funnelling at a single interface and adiabatic plasmonic focusing. By combining adiabatic plasmonic focusing with Brewster energy funnelling the inventors have achieved, at the same time, ultrabroadband impedance matching, minimizing reflections and realizing omnidirectional absorption over a broader frequency spectrum, including optical and a large part of the IR spectrum.

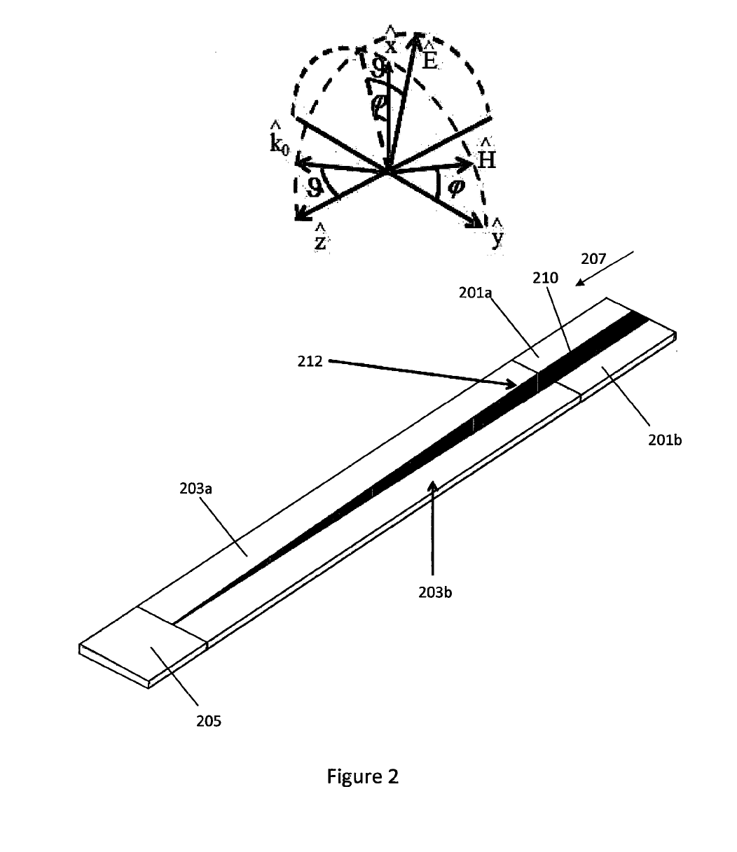

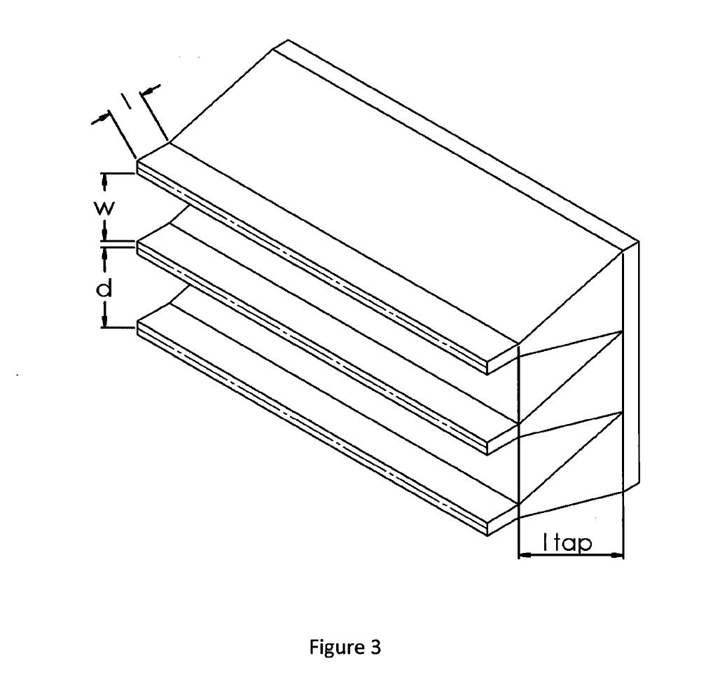

This mechanism may be better understood with reference to FIGS. 2 and 3. FIG. 2 shows a cross-section of an example unit cell which extends in the third direction (the x-direction of FIG. 2) and repeats to form a grating-type structure as shown in FIG. 3. In an embodiment, the period of the grating-type structure is sub-wavelength (that is, less than a wavelength of the incident radiation). In this embodiment, it may therefore be understood that the material element is an elongated cuboid.

As well as relating to a one-dimensional array rather than a two-dimensional array, it should be noted that FIG. 2 may be considered as the inverse of FIG. 1 in that the unit cell shown relates to the space 210 between two halves of adjacent material elements 201a and 201b. Likewise, FIG. 2 shows the space 212 between two halves of the corresponding adjacent tapered waveguides 203a and 203b. In operation, incident light 207 is received at a first plane—comprising the plurality of material elements 201a, 201b—and guided towards a second place 205.

There is therefore provided an optical waveguide comprising: a periodic component comprising a plurality of material elements arranged to receive radiation; and a plurality of tapered waveguides, wherein each material element is respectively coupled to a tapered waveguide which tapers outwardly from the material element.

Notably, the inventors have recognised that coupling each material element with a tapered waveguide provides improved light guiding and omnidirection coupling of radiation incident on the material elements. In particular, whilst an angle for optimum absorption may be found, significant absorption occurs at a range of angles owing to the tapered waveguides. It can be understood that the optical waveguide in accordance with the present disclosure may be considered to be pseudo omnidirectional.

In embodiments, the periodic component has a first dimension no greater than a wavelength of the received radiation. For example, in an embodiment, the first dimension is between 1 nanometre (nm) and 8 micrometres (μm). Advantageously, in embodiments related to optical frequencies, the first dimension is between 1 nm and 100 nm.

In an embodiment, each material element has a first dimension no greater than a wavelength of the received radiation. For example, in an embodiment, the spacing between adjacent material elements is between 1 nanometre (nm) and 8 micrometres (μm). Advantageously, in embodiments related to optical frequencies, the spacing between adjacent elements is between 1 nm and 100 nm.

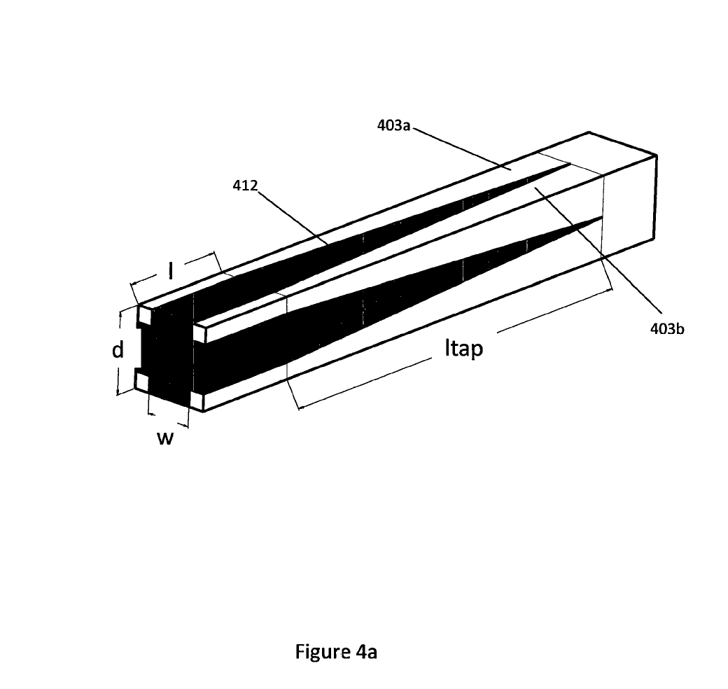

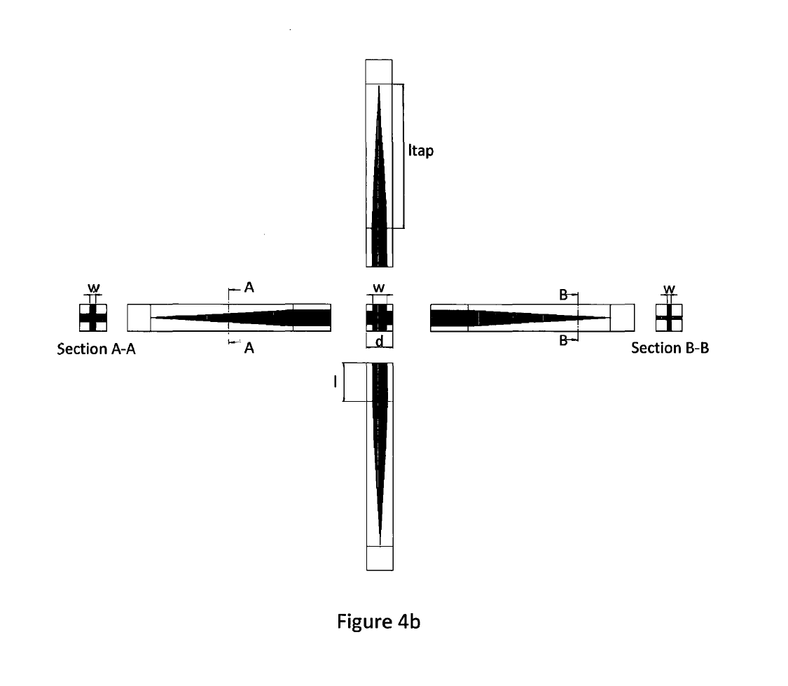

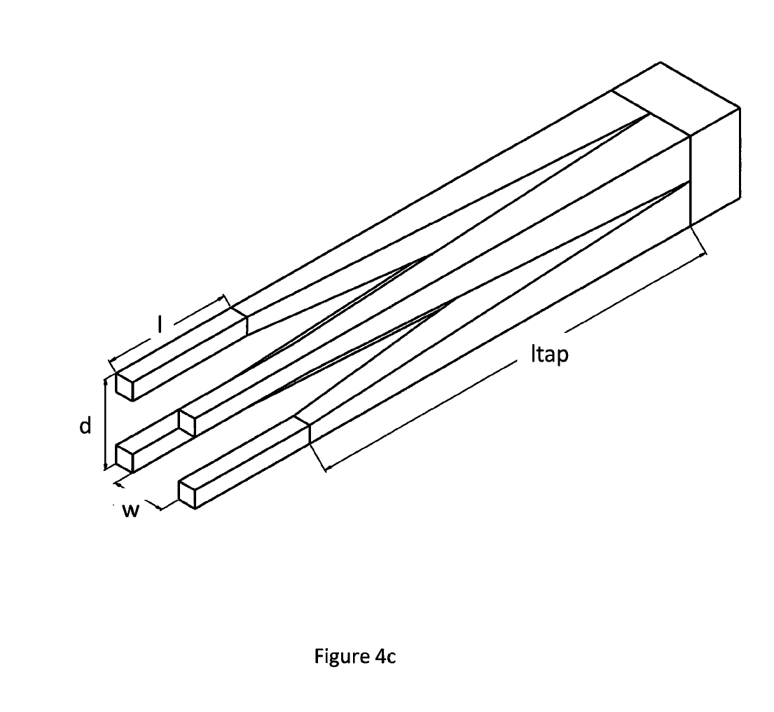

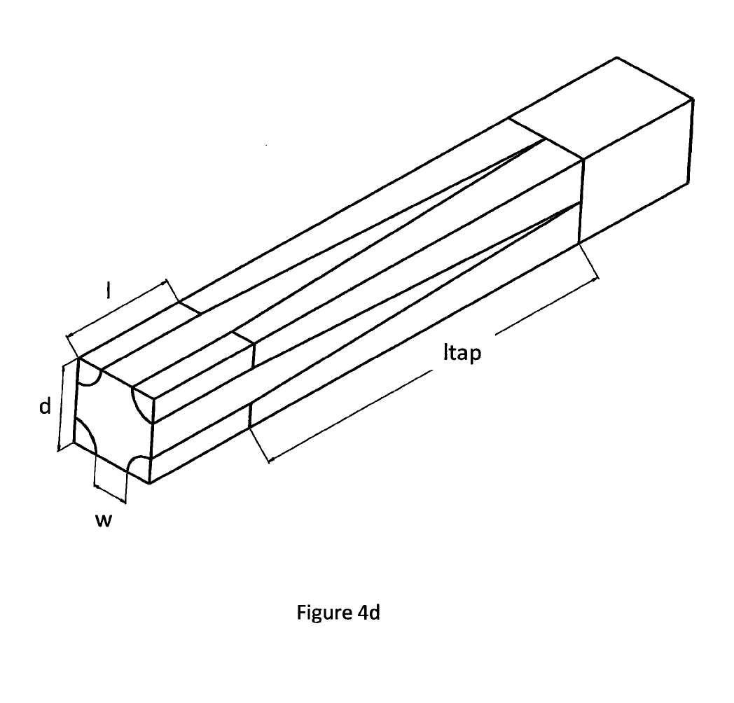

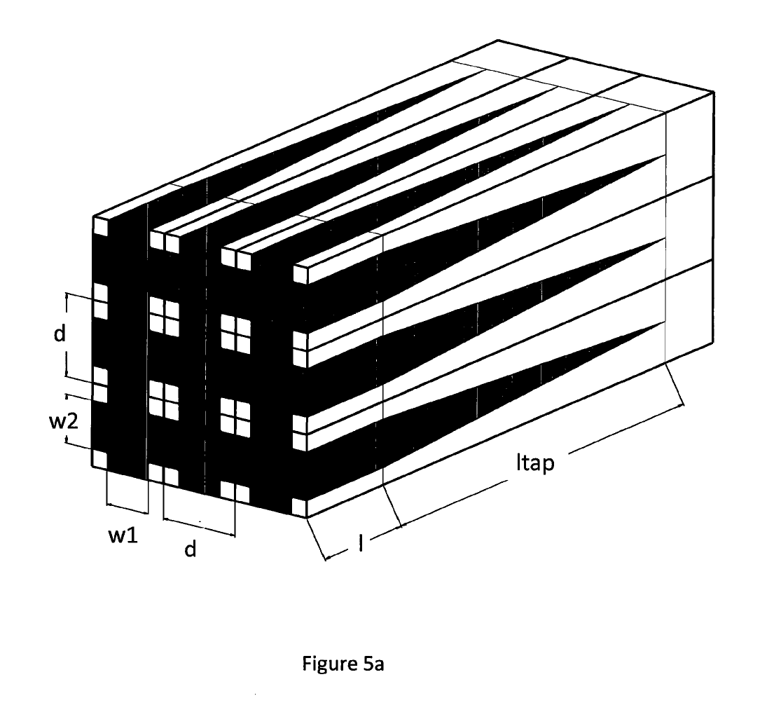

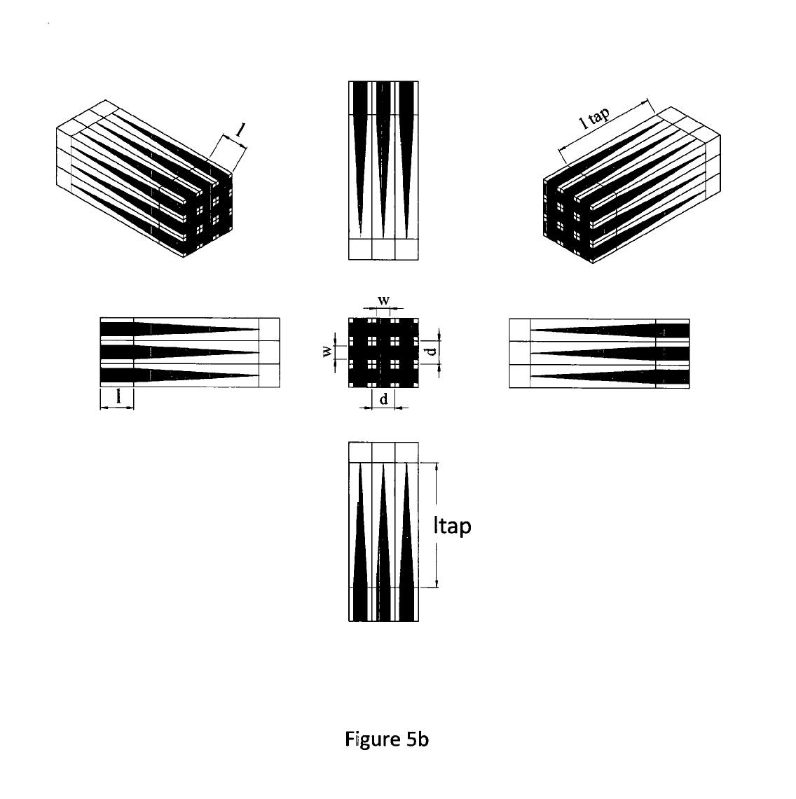

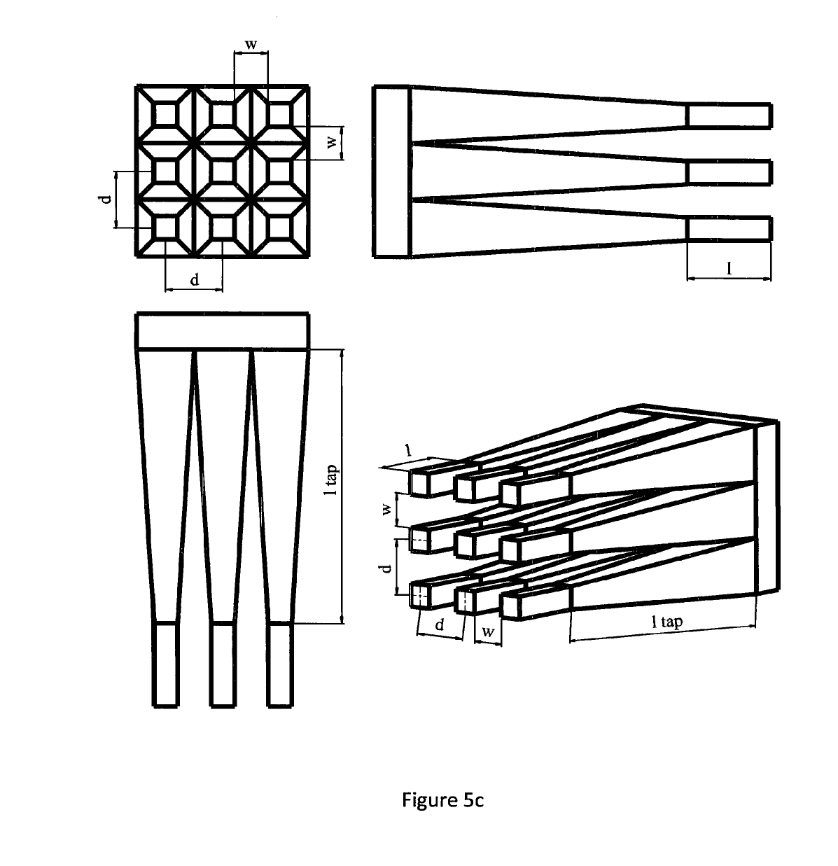

FIG. 4a shows a section of a further embodiment comprising a two-dimensional array of cuboid-shaped material elements having a space or gap 412 between adjacent tapered waveguides 403a, 403b. FIG. 4b shows various planes of the same structure. FIG. 4c shows a two-dimensional array of four material elements and tapered waveguides, wherein the material elements are cuboid-shaped. FIG. 4d shows a unit cell for a waveguide comprising cylindrical material elements. Likewise, FIGS. 5a, 5b and 5c show an optical waveguide comprising a plurality of nine unit cells (of FIG. 4) arranged in a two-dimensional array. To reiterate, FIGS. 5a, 5b and 5c show the same general structure. FIGS. 5a and 5b highlight the spacing between the material elements and tapered waveguides. FIG. 5c highlights the material elements and tapered waveguides themselves.

It may therefore be understood from at least FIGS. 4 and 5 that, in embodiments, the plurality of material elements are arranged in a two-dimensional array on a first plane. However, as shown in FIGS. 2 and 3, the present disclosure is equally applicable to one-dimensional arrays of unit cells.

In an embodiment, the tapered waveguides may taper outwardly from the material elements to a common plane. That is, in an embodiment, the tapered waveguides taper outwardly from a first plane to a second plane. Optionally, the second plane may be reflective or may comprise a reflective component arranged to redirect guided radiation back towards the first plane.

In embodiments, Brewster light funnelling is achieved at the first plane by using material elements and/or tapered waveguides which comprise a material having a negative dielectric permittivity—for example, metal. That is, in an embodiment, the material elements and/or tapered waveguides are metallic or formed from a material which exhibits metallic behaviour at the frequency of the incident radiation. That is, for optical frequencies, a so-called plasmonic material. For example, for optical frequencies, the material elements and/or tapered waveguides may be formed from at least one selected from the group comprising: gold, silver and alumina.

In the embodiment shown in FIG. 1, the material elements 101 are cuboid. However, in other embodiments, the material elements may be any shape having symmetry in two orthogonal directions such as a cylinder, hexagon or polygon, optionally, having at least one sub-wavelength dimension.

In accordance with the present disclosure, the plurality of material elements are respectively tailored to impedance match incoming radiation. Without being constrained by theory, this is achieved by minimizing to zero the reflection coefficient which is given by:

$$R = \frac{( {Z}_{s}^{2} - {Z}_{in} {Z}_{out} ) tan ( {β}_{s} l ) - i ( {Z}_{in} - {Z}_{out} ) {Z}_{s}}{( {Z}_{s}^{2} + {Z}_{in} {Z}_{out} ) tan ( {β}_{s} l ) + i ( {Z}_{in} + {Z}_{out} ) {Z}_{s}} \qquad ( 1 )$$

where Zᵢₙ and Zₒᵤₜ are the general input and output characteristic impedances of the system, βs is the wave number in the plasmonic waveguide, l is the length of the waveguide, and Zₛ is its characteristic impedance per unit length which is defined through the ratio of the effective voltage and the effective current as follows:

$${Z}_{s} = \frac{{V}_{s}}{{I}_{s}} = \frac{{\int }_{0}^{w} {E}_{x} d x}{{ωɛ}_{0} {ɛ}_{s} {E}_{x} / {β}_{s}} \qquad ( 2 )$$

where εₛ is the relative permittivity of the material filling the waveguide and Eₓ the electric field along its entrance, which is integrated along that direction to calculate the characteristic voltage. The characteristic impedances of the input and (optionally) the output media for a wave propagating at angle θ with respect to the interface are given by the ratio between the tangential electric and magnetic fields, normalized to the grating period, for non-magnetic media they are given by:

$${Z}_{in} = \sqrt{\frac{{μ}_{0}}{{ɛ}_{in} {ɛ}_{0}}} d cos ( θ ) \\ {Z}_{out} = \sqrt{\frac{{μ}_{0}}{{ɛ}_{out} {ɛ}_{0}}} d \sqrt{1 - \frac{{sin}^{2} ( θ )}{{ɛ}_{out}}} \qquad ( 3 )$$

Here εᵢₙ and εₒᵤₜ are the relative permittivities of the input and output media, respectively.

Thus, the condition R=0 for a given geometry (i.e. known Zᵢₙ, Zₒᵤₜ, Zₛ) provides the angle at which maximum coupling occurs. Similarly, the geometry of a grating can be designed using Equations (1), (2) and (3) to provide maximum coupling at a predetermined angle.

The structure of FIG. 3 may be considered a one-dimensional (1D) grating with period d, formed by an array of slits carved in a host medium and infinitely extended along y with unit cell shown in FIG. 3. The slits have width w and length l, terminated by a taper designed to adiabatically dissipate the energy transmitted through the slits. The taper is then optionally terminated by a back plate much thicker than the skin depth. The permittivity of the host medium can be modelled with a Drude dispersion model. Along one dimension of this rectangular grating, this condition R=0 simplifies to the following equation for the incident angle:

$$cos {θ}_{B} = \frac{{β}_{s} w}{{ɛ}_{s} {k}_{0} d} , \qquad ( 4 )$$

where εₛ is the material permittivity filling the slits and k₀ is the free-space wave number. In that special case the impedance of the waveguides is given by:

Zₛ=wβₛ/(ωε₀ε_{w}) (5)

while the propagation constant βs is the solution of the equation:

$$tanh [ \sqrt{{β}_{s}^{2} - {ɛ}_{s} {k}_{0}^{2}} w / 2 ] \sqrt{{β}_{s}^{2} - {ɛ}_{s} {k}_{0}^{2}} = - \frac{{ɛ}_{s}}{{ɛ}_{m}} \sqrt{{β}_{s}^{2} - {k}_{0}^{2} {ɛ}_{m}} \qquad ( 6 )$$

where εₘ is the relative permittivity of the material creating the tapered waveguide.

At this angle θ_{B}, similar to the Brewster condition for a homogeneous interface, zero reflection and total transmission through the interface—comprising the plurality of material elements—are expected. This phenomenon weakly depends on frequency, as long as the plasmonic mode in the slit is weakly dispersive. This simple analytical model is a very accurate description of the anomalous funnelling mechanism through the slits as long as the wavelength is longer than d, ensuring that the impinging energy can funnel into the slits from DC to very high frequencies.

This funnelling phenomenon is purely based on impedance matching, without requiring any resonance, and therefore the transmitted wave may be fully absorbed into the slits without affecting at all the reflection coefficient or the bandwidth of operation. This functionality is very different from any other tunnelling mechanism through narrow slits relying on resonant mechanisms, which would be severely affected by absorption. Absorption is achieved in accordance with the present disclosure by using a taper behind the Brewster interface, which adiabatically absorbs the transmitted plasmonic mode without reflections. The tapering angle and the corresponding length, ltap, determine the largest wavelength over which the transmitted energy gets fully absorbed in the metallic walls by the time it reaches the taper termination. Since the efficiency of adiabatic absorption depends on the taper length compared to the excitation wavelength, in fact, a given choice of tapering length fixes the limit on the minimum frequency of operation to achieve perfect absorption.

In an embodiment using cuboid-shaped material elements, the parameters for the 1D grating may be, for example, d=96 nm, w=24 nm, l=200 nm, and ltap=980 nm to support Brewster funnelling at 70° as predicted by Equation (4). However, the skilled person will understand that other parameters may be used. In advantageous embodiments: d is 10 nm to 1000 nm; w is 2 nm to 1000 nm (but less than d); l is less than 10 μm; and/or ltap is less than 100 μm (i.e. up to several wavelengths long) for omnidirectional Brewster funnelling of optical radiation using plasmonic material elements and tapered waveguides.

The inventors have provided an optical waveguide in which, around the Brewster angle, total absorption of the incident radiation into the waveguide may be achieved over a very broad range of wavelengths. The inventors have further found that this range may be further broadened, as the upper cut-off (shorter wavelength) is determined by the transverse period, whereas the lower limit is fixed by the taper length. In an embodiment, the angular range of absorption is controlled by the ratio d/w. Therefore large absorption is achieved for all incident angles in the frequency range of interest, even at normal incidence, except for angles very close to grazing incidence beyond the Brewster angle.

The Brewster funnelling concept can be extended to two-dimensions (see, for example, FIGS. 4 and 5), showing that a mesh of orthogonal slits may provide funnelling independent of the plane of polarization. In these embodiments, the structure is formed by crossed slits, tapered in 2D to allow adiabatic focusing and absorption (and reciprocally emission) on all planes of TM polarization. In order to test performance in both absorption and emission, one may analyze functionality in the worst-case scenario of an azimuthal angle φ=45° between the two orthogonal sets of slits.

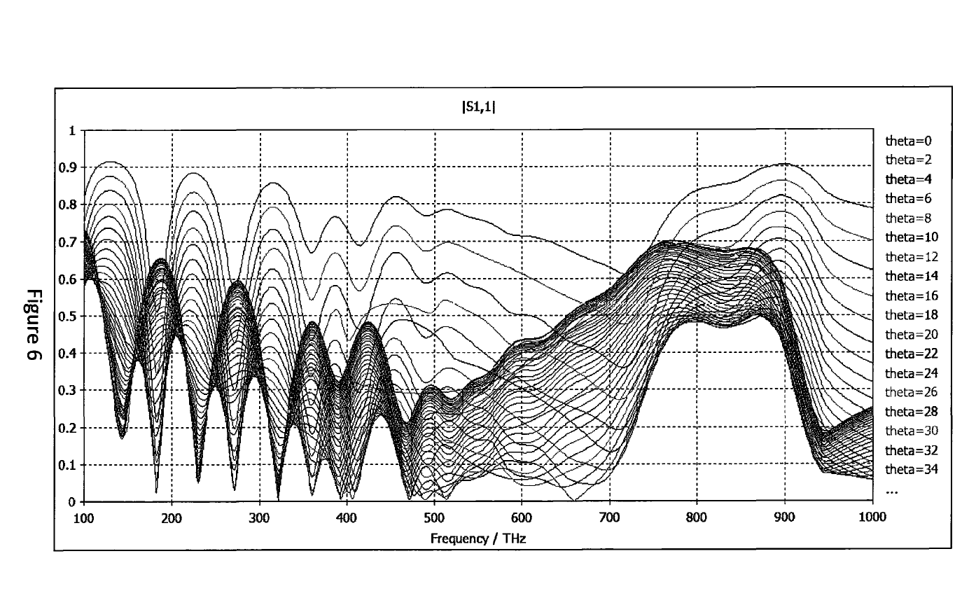

FIG. 6 shows the reflection (S11 parameter) of the incident electric field in the 1D structure of FIG. 2, as the angle of the incident field is varied from 0 to 90 degrees. Significant amount of energy is coupled into the structure over a broadband wavelength range, except for grazing angles of incidence. The absorption can be further improved and tuned by varying the geometric parameters of the structure.

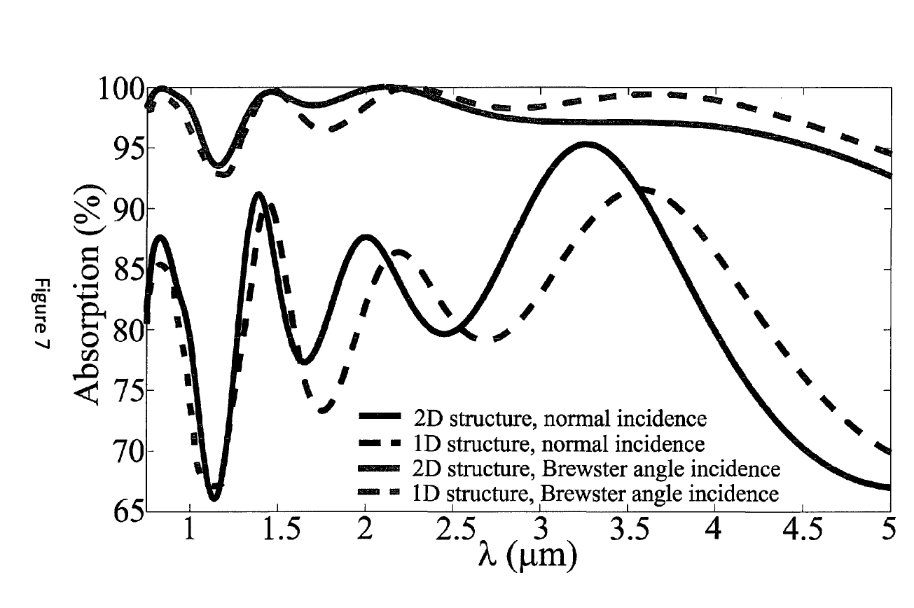

FIG. 7 compares the performance of a 1D optical waveguide at normal incidence and at the Brewster angle 70° with the equivalent 2D case monitored on the φ=45° plane (which is the worst-case scenario), obtained by providing another set of orthogonal slits with same period and width, as shown in FIG. 3. In this example, the material elements are gold and the tapered waveguides are separated by air. It may be noted that the 2D device has remarkably similar performance to the 1D device, extending its functionality to all polarization planes. As expected, both devices show very large, broadband absorption, especially large at the Brewster angle (upper lines), but consistently large for any angle, even at normal incidence (lower lines).

Advantageously, it may be understood that the optical waveguide in accordance with the present disclosure does not require energy input such as from a power source or an active control system. That is, in embodiments, the optical waveguide is passive.

In further advantageous embodiments, the optical waveguide in accordance with the present disclosure may be used in a photovoltaic device.

Notably, in a further improvement, the inventors have recognised that the space, or gaps, between the tapered waveguides may be filled with an absorbing or photovoltaic material which converts light into an electric current and then a voltage. Accordingly, the inventors have found that highly efficient conversion of light into voltage is achieved. In particular gains may be provided by tuning the parameters of the waveguide to the photovoltaic material.

In an embodiment, the photovoltaic component is interleaved between the tapered waveguides. Likewise, in an embodiment, the photovoltaic component has a shape complementary to the tapered waveguides.

The skilled person will understand that the photovoltaic component is arranged to absorb light guided by the optical waveguide.

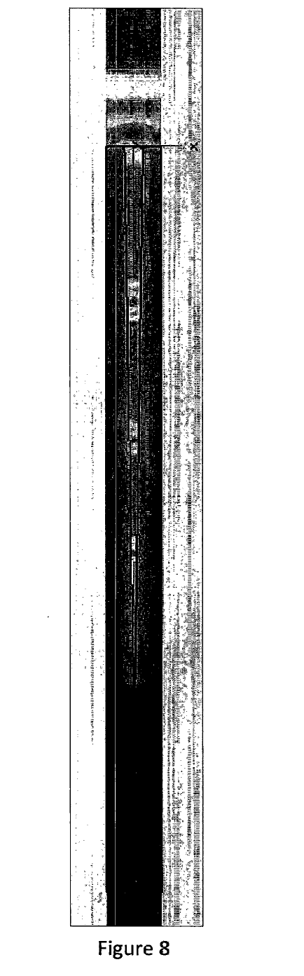

FIG. 8 shows the simulated electric field amplitude distribution in a slice of the tapered waveguide structure of FIG. 3. The incident field is coupled into the optical waveguide with an increased intensity in the tapered region, which is filled (interleaved) with a photovoltaic material with tan δ=0.1.

The skilled person will understand that any photovoltaic component may be suitable in accordance with the present disclosure. For example, in an embodiment, the photovoltaic component is formed of at least one selected from the group comprising silicon, germanium, gallium arsenide and silicon carbide. In other embodiments, the photovoltaic component is cadmium telluride or copper indium gallium selenide/sulphide. It can be understood from the present disclosure that other semiconductors may be equally suitable.

In an embodiment, the photovoltaic device may be solar cell. This is particularly advantageous because of the omnidirectional nature of the optical waveguide.

It may be recognised that the optical waveguide in accordance with the present disclosure works for multiple angles of incidence and for all polarizations and provides broadband absorption with very high efficiency.

The optical waveguide in accordance with the present disclosure may be fabricated by electron beam lithography, focused ion beam lithography, lift-off processes, or other lithographic techniques. These techniques may be used to form the components having the sub-wavelength parameters and characteristics disclosed herein.

Although aspects and embodiments have been described, variations can be made without departing from the inventive concepts disclosed herein.

1. An optical waveguide comprising:
a periodic component comprising a plurality of material elements arranged to receive radiation; and
a plurality of tapered waveguides, wherein each material element is respectively coupled to a tapered waveguide which tapers outwardly from the material element.

2. An optical waveguide as claimed in claim 1 wherein the plurality of material elements and/or plurality of tapered waveguides are metamaterials.

3. An optical waveguide as claimed in claim 1 wherein the material elements and/or tapered waveguides are plasmonic.

4. An optical waveguide as claimed in claim 1 wherein the material elements and/or tapered waveguides comprise a material having a negative dielectric permittivity.

5. An optical waveguide as claimed in claim 1 wherein the material elements and/or tapered waveguides are metallic, optionally, at least one selected from the group comprising: gold, silver and alumina.

6. An optical waveguide as claimed in claim 1 wherein the periodic component has a first dimension no greater than a wavelength of the received radiation.

7. An optical waveguide as claimed in claim 1 wherein each material element has a first dimension no greater than a wavelength of the received radiation.

8. An optical waveguide as claimed in claim 1 wherein the first dimension is between 1 nm and 8 μm.

9. An optical waveguide as claimed in claim 1 wherein the spacing between adjacent material elements is between 1 nm and 8 μm.

10. An optical waveguide as claimed in claim 1 wherein the plurality of material elements are arranged in a two-dimensional array on a first plane.

11. An optical waveguide as claimed in claim 1 wherein the tapered waveguides taper outwardly from the first plane to a second plane.

12. An optical waveguide as claimed in claim 1 wherein the second plane comprises a reflector.

13. An optical waveguide as claimed in claim 1 wherein the material elements are symmetric in two orthogonal directions.

14. An optical waveguide as claimed in claim 1 wherein the optical waveguide is passive.

15. A photovoltaic device comprising an optical waveguide as claimed in claim 1.

16. A photovoltaic device as claimed in claim 15 further comprising:
a photovoltaic component interleaved between the tapered waveguides.

17. A photovoltaic device as claimed in claim 16 wherein the photovoltaic component is arranged to absorb light guided by the optical waveguide.

18. A photovoltaic device as claimed in claim 16 wherein the photovoltaic component has a shaped complementary to the tapered waveguides.

19. A photovoltaic device as claimed in claim 16 wherein photovoltaic component is formed of least one selected from the group comprising: silicon, germanium, gallium arsenide and silicon carbide.

20. A photovoltaic device as claimed in claim 15 wherein the photovoltaic device is a solar cell.

21. (canceled)
